(19) United States
(12) Patent Application Publication
(10) Pub. No.: US 2013/0293295 A1
(43) Pub. Date: Nov. 7, 2013

(54) COMPACT RF POWER AMPLIFIER

(71) Applicant: ELECTRONICS AND TELECOMMUNICATIONS RESEARCH INSTITUTE, Daejeon (KR)

(72) Inventors: Youn Sub NOH, Daejeon (KR); In Bok YOM, Daejeon (KR); Dong Pil CHANG, Daejeon (KR); Hong Gu JI, Daejeon (KR)

(73) Assignee: Electronics and Telecommunications Research Institute, Daejeon (KR)

(21) Appl. No.: 13/832,452

(22) Filed: Mar. 15, 2013

(30) Foreign Application Priority Data
May 2, 2012 (KR) 10-2012-0046539
Nov. 6, 2012 (KR) 10-2012-0124823

(51) Int. Cl. H03F 3/60

(52) U.S. Cl. CPC H03F 3/602
USPC 330/124 R

(57) ABSTRACT

Provided is a compact RF power amplifier including: a Doherty amplifier comprising a carrier amplifier comprising a first input impedance matching unit, a first amplifier, and a first output impedance matching unit, and a peaking amplifier comprising a second input impedance matching unit, a second amplifier, and a second output impedance matching unit, in which when a power level of the first RF amplified signal reaches a predetermined power level, the peaking amplifier outputs the second RF amplified signal.

### CROSS-REFERENCE TO RELATED APPLICATIONS

This application claims priority to and the benefit of Korean Patent Application No. 10-2012-0046539 filed on May 2, 2012 and 10-2012-0124823 filed on Nov. 6, 2012 in the Korean Intellectual Property Office, the entire contents of which are incorporated herein by reference.

### TECHNICAL FIELD

The present invention relates to a compact RF power amplifier, and more particularly, to a compact RF power amplifier which is easily applied to an array antenna system and has a high efficiency characteristic.

### BACKGROUND ART

In general, a power amplifier of a terminal for mobile communication, a repeater, and a base station is operated with a sufficient peak-to-average ratio (PAR). Accordingly, an RF power amplifier having a power characteristic of high output is designed using a Doherty structure, which has an excellent efficiency characteristic. When a Doherty amplifier is used, it is possible to obtain a high efficiency characteristic in back-off output power at several dBs with saturated output power, such that the Doherty amplifier is a technology widely used in a high linearity communication system. Since technologies up to the present adopt a method of designing an input and output matching circuit by using an LDMOS or GaN transistor bar from the outside, there is a limitation in decreasing a size of a Doherty amplifier module. However, a recent array antenna system requires several to several tens of transceiving modules, such that it is necessary to design the transceiving module needs to have a compact size. Accordingly, only when a power amplifier module is also designed to be compact, the power amplifier module can be applied to the array antenna system.

### SUMMARY OF THE INVENTION

The present invention has been made in an effort to provide a compact RF power amplifier which is easily applied to an array antenna system and has a high efficiency characteristic.

An exemplary embodiment of the present invention provides a compact RF power amplifier, including: a Doherty amplifier including a carrier amplifier including a first input impedance matching unit configured to match input impedance of an input first RF signal, a first amplifier configured to amplify the first RF signal matched by the first input impedance matching unit to a first RF amplified signal, and a first output impedance matching unit configured to match output impedance of the first RF amplified signal, and a peaking amplifier including a second input impedance matching unit configured to match input impedance of input second RF signal, a second amplifier configured to amplify the second RF signal matched by the second input impedance matching unit to a second RF amplified signal, and a second output impedance matching unit configured to match output impedance of the second RF amplified signal, in which when a power level of the first RF amplified signal reaches a predetermined power level, the peaking amplifier outputs the second RF amplified signal.

Another exemplary embodiment of the present invention provides a compact RF power amplifier, including: a Doherty amplifier including a carrier amplifier including a first input impedance matching unit configured to match input impedance of an input first RF signal, a first amplifier configured to amplify the first RF signal matched by the first input impedance matching unit to a first RF amplified signal, and a first output impedance matching unit configured to match output impedance of the first RF amplified signal, and a peaking amplifier including a second input impedance matching unit configured to match input impedance of input second RF signal, a second amplifier configured to amplify the second RF signal matched by the second input impedance matching unit to a second RF amplified signal, and a second output impedance matching unit configured to match output impedance of the second RF amplified signal; a first quarter wave transformer connected to the first output impedance matching unit, and configured to maintain the first RF amplified signal with impedance of 50Ω; and a second quarter wave transformer connected to the first quarter wave transformer and the second output impedance matching unit, and configured to output a third RF signal combined with at least one of the first and second RF amplified signals, in which when a power level of the first RF amplified signal reaches a predetermined power level, the peaking amplifier outputs the second RF amplified signal, and the third RF signal is the same as the first RF amplified signal before the predetermined power level, and is the same as a combined signal of the first and second RF amplified signals after the predetermined power level.

In the compact RF power amplifier according to the exemplary embodiments, the Doherty amplifier with high output and high efficiency may be implemented as a microwave monolithic integrated circuit (MMIC) chip, thereby reducing manufacturing costs and simplifying a manufacturing process.

In the compact RF power amplifier according to the exemplary embodiment, the output impedance matching unit of the peaking amplifier makes the first RF amplified signal be maintained with high impedance of infinite (∞) Ω before the first RF amplified signal output from the carrier amplifier reaches the predetermined power level, and makes the first RF amplified signal with impedance of 50Ω when the first RF amplified signal reaches the predetermined power level, so that there is a merit in that a compensation line may not be implemented.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a control block diagram illustrating a compact RF power amplifier according to an exemplary embodiment.

FIGS. 2A to 2C are waveform diagrams illustrating output waveforms for the compact RF power amplifier illustrated in FIG. 1.

FIG. 3 is a Smith chart illustrating a matching point of a peaking amplifier included in the compact RF power amplifier illustrated in FIG. 1.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

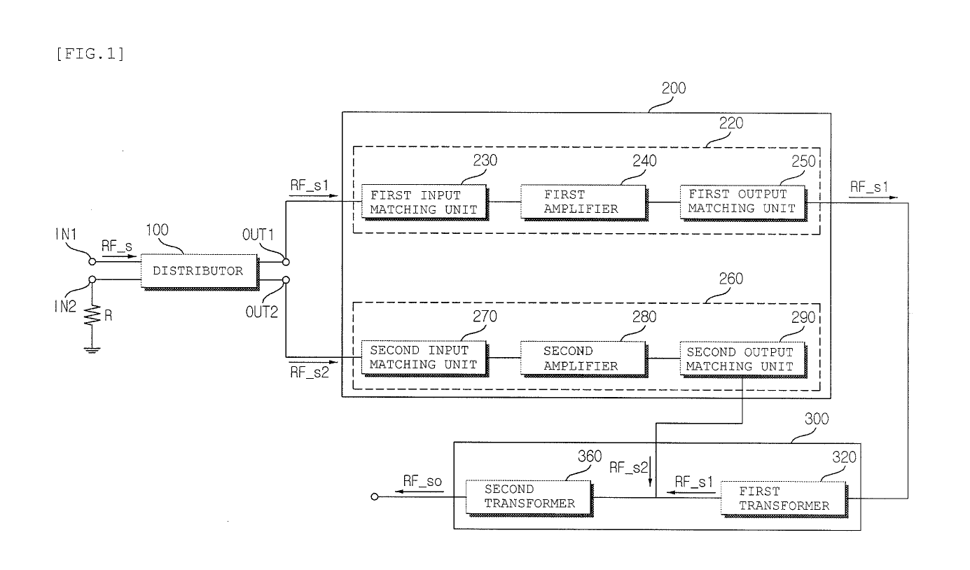

Hereinafter, a compact RF power amplifier according to an exemplary embodiment will be described in detail based on parts necessary for understanding an operation and an action with reference to accompanying FIGS. 1 to 3.

In describing constituent elements of an exemplary embodiment, different reference numbers may refer to like elements depending on the drawing, and like reference numerals may refer to like elements even though like elements are shown in different drawings. However, even in this case, it is not meant that a corresponding constituent element has a different function according to an exemplary embodiment or has the same function in different exemplary embodiments, and a function of each constituent element may be determined based on a description of each constituent element in a corresponding exemplary embodiment.

In the following description of the exemplary embodiment, a detailed description of known functions and configurations incorporated herein will be omitted to avoid making the subject matter of the present invention unclear.

In describing the constructional elements of the exemplary embodiment, the terms of a first, a second, A, B, (a), (b), or the like, may be used. Such a term is only for discriminating the constituent element from another constituent element, and does not limit the essential feature, order, or sequence of the constituent element, or the like. If one constituent element is “coupled to”, “assembled with”, or “connected to” another constituent element, the one constituent element is directly coupled to or connected to another constituent element, but it can be understood that another different constituent element can be “coupled”, “assembled”, or “connected” between constituent elements.

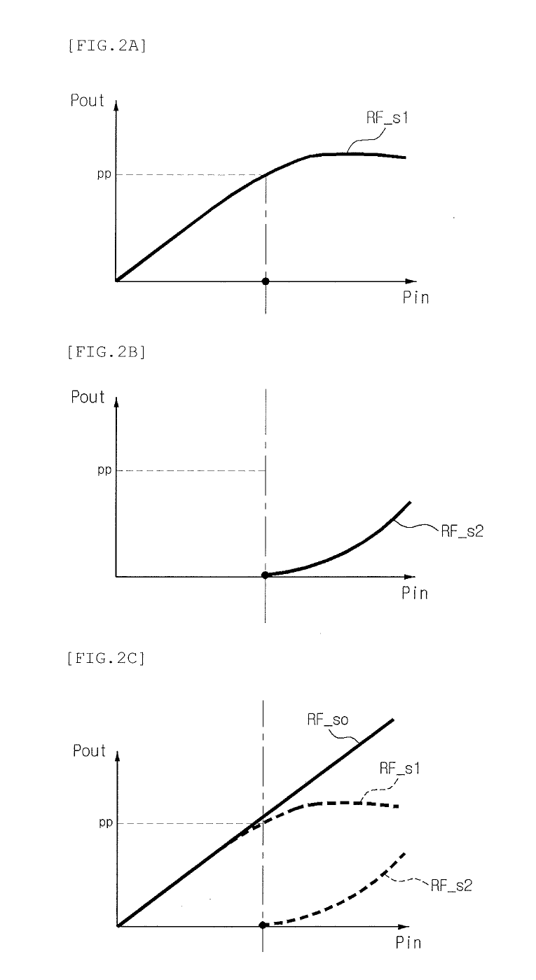

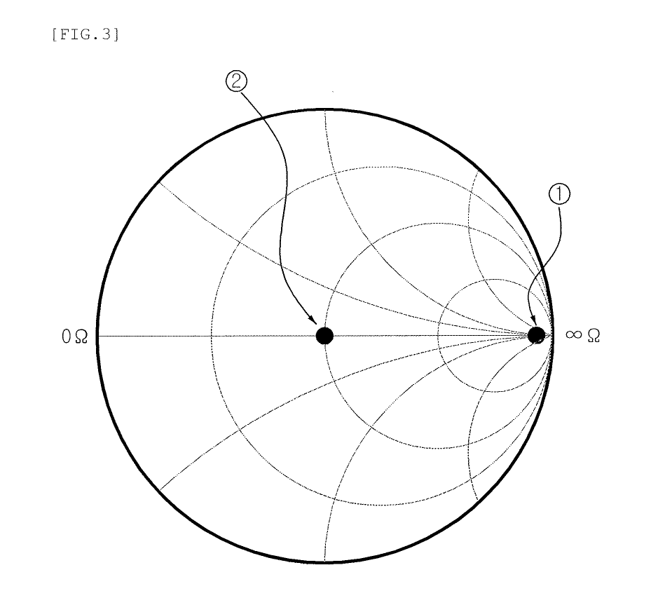

FIG. 1 is a control block diagram illustrating a compact RF power amplifier according to an exemplary embodiment, FIGS. 2A to 2C are waveform diagrams illustrating output waveforms for the compact RF power amplifier illustrated in FIG. 1, and FIG. 3 is a Smith chart illustrating a matching point of a peaking amplifier included in the compact RF power amplifier illustrated in FIG. 1.

Referring to FIGS. 1 to 3, the compact RF power amplifier may include a distributor 100, a Doherty amplifier 200 including a carrier amplifier 220 and a peaking amplifier 260, and a transformer 300.

The distributor 100 may be a power divider or a hybrid coupler, and the distributor 100 in the exemplary embodiment is described as a hybrid coupler, but is not limited thereto.

The distributor 100 may include a first terminal IN1 in which an input RF signal RF_s is input, a first output terminal OUT1 through which a first RF signal RF_s1, to which input power is distributed from the input RF signal RF_s, is output to the carrier amplifier 220, a second output terminal OUT2 through which a second RF signal RF_s2, to which input power is distributed from the input RF signal RF_s and which has a phase delay of 90° compared to the first RF signal RF_s1, is output to the peaking amplifier 260, and a second terminal IN2 connected to resistance R for matching impedance for the input RF signal RF_s.

The distributor 100 may be implemented as a transmission line, such as a coupled line coupler, a Lange coupler, and a branch line coupler, and may also be implemented by a low temperature co-fired ceramic (LTCC) method, but is not limited thereto.

The Doherty amplifier 200 may include the carrier amplifier 220 for amplifying the first RF signal RF_s1 output from the first output terminal OUT1 of the distributor 100, and the peaking amplifier 260 for amplifying the second RF signal RF_s2 output from the second output terminal OUT2 of the distributor 100.

Here, the carrier amplifier 220 may include a first input impedance matching unit 230 for linearly amplifying a carrier and matching input impedance of the first RF signal RF_s1 when the first RF signal RF_s1 is input, a first amplifier 240 for amplifying the first RF signal RF_s1 output from the first input impedance matching unit 230, and a first output impedance matching unit 250 for matching output impedance for the first RF signal RF_s1 amplified by the first amplifier 240.

The peaking amplifier 260 may include a second input impedance matching unit 270 for matching input impedance of the second RF signal RF_s2 when the second RF signal RF_s2 is input, a second amplifier 280 for amplifying the second RF signal RF_s2 output from the second input impedance matching unit 270, and a second output impedance matching unit 290 for matching output impedance for the second RF signal RF_s2 amplified by the second amplifier 280.

That is, when power of the first RF signal RF_s1 output from the carrier amplifier 220 is increased to a predetermined power level and then is constantly maintained at the predetermined power level, that is, when the power of the first RF signal RF_s1 reaches the predetermined power level, the peaking amplifier 260 may output the second RF signal RF_s2.

In other words, the peaking amplifier 260 may not output the second RF signal RF_s2 before the first RF signal RF_s1 output from the carrier amplifier 220 reaches the predetermined power level.

Here, the first and second input impedance matching units 230 and 270 may make the input power of the first and second RF signals RF_s1 and RF_s2 be amplified by the first and second amplifiers 240 and 280 by optimizing the input power of the first and second RF signals RF_s1 and RF_s2.

In this case, the first and second amplifiers 240 and 280 may be an amplifier including a transistor, for example, at least one of a BJT and a FET, but are not limited thereto.

Here, a size ratio of the transistors included in the first and second amplifiers 240 and 280 may determine ranges of output regions for minimum output and maximum output of the Doherty amplifier 200.

The first output impedance matching unit 250 may match output impedance of the first RF signal RF_s1 amplified by the first amplifier 240, and the second output impedance matching unit 290 may match output impedance of the second RF signal RF_s2 amplified by the second amplifier 280.

In this case, when the power of the first RF signal RF_s1 is lower than the predetermined power level, the second output impedance matching unit 290 makes the first RF signal RF_s1 have impedance of 500Ω to 5,000Ω, that is, infinite impedance ∞Ω, so that the second RF signal RF_s2 is not output, and when the power of the first RF signal RF_s1 is equal to or higher than the predetermined power level, the second output impedance matching unit 290 makes the first RF signal RF_s1 be maintained with impedance of 45Ω to 55Ω, so that the second RF signal RF_s2 may be output.

The Doherty amplifier 200 illustrated in the exemplary embodiment may be implemented as a microwave monolithic integrated circuit (MMIC) chip, so that the Doherty amplifier may be manufactured to be compact.

In the RF power amplifier in the related art, a compensation line for compensating impedance is disposed between the Doherty amplifier and the transformer to adjust a matching point by compensating for the impedance of a signal output from the peaking amplifier, and thus cannot be implemented as a single MMIC chip. However, in the RF power amplifier in the exemplary embodiment, it is possible to remove a compensation line used in the related art by adjusting a value of L and a value of C of a coil (inductor) and a capacitor included in the second output impedance matching unit 290, so that the Doherty amplifier may be implemented as a single MMIC chip, thereby implementing the compact RF power amplifier.

The transformer 300 may include a first quarter wave transformer 320 connected to the first output impedance matching unit 250 included in the carrier amplifier 220 and maintaining the first RF signal RF_s1 with impedance of 50Ω, and a second quarter wave transformer 360 connected to the first quarter wave transformer 320 and the second output impedance matching unit 290 included in the peaking amplifier 260, and outputting a third RF signal RF_so combined with at least one of the first and second RF signals RF_s1 and RF_s2.

Here, the description will be made with reference to FIGS. 2 to 3.

FIG. 2A represents power of the first RF signal RF_s1 output from the carrier amplifier 220, FIG. 2B represents power of the second RF signal RF_s2 output from the peaking amplifier 260, and FIG. 2C represents power of the third RF signal RF_s0 output from the second quarter wave transformer 360.

FIG. 3 illustrates a Smith chart illustrating an operation point when the peaking amplifier 260 is operated in a level of class C.

That is, the peaking amplifier 260 may adjust a value of L and a value of C of the coil and the capacitor included in the second output impedance matching unit 290 so that the Doherty amplifier 200 has output impedance of high impedance ∞ of a first position \textcircled{0} when the Doherty amplifier 200 is operated as illustrated in FIG. 2A at a lower output power level, that is, a predetermined power level pp as illustrated in FIG. 2B.

When the Doherty amplifier 200 is operated at a high output power level, that is, a level equal to or higher than the predetermined power level pp as illustrated in FIGS. 2A and 2B, the matching point is converted so that the output impedance has low impedance (approximately 50Ω) of a second position \textcircled{2}, and thus the peaking amplifier 260 may have a high output power characteristic.

Accordingly, the third RF signal RF_s3 illustrated in FIG. 2C may be the same as the first RF signal RF_s1 in a level lower than the predetermined power level pp, and may be the same as a signal combined with the first and second RF signals RF_s1 and RF_s2 at a level equal to or higher than the predetermined power level pp.

Accordingly, in the RF power amplifier in the exemplary embodiment, it is possible to remove the compensation line used in the related art, and there is no power loss due to the compensation line in the related art, so that there are merits in that the Doherty amplifier 200 may be implemented as a single MMIC chip, thereby achieving a small size, and it is possible to design an amplifier having high efficiency.

As described above, the Doherty amplifier in the exemplary embodiment includes the carrier amplifier and the peaking amplifier including the first and second input and output matching units included in the MMIC chip in order to make the entire structure be compact (that is, the amplifier with one stage or multi stages is designed in the MMIC type) and impedance when the second output matching unit of the peaking amplifier is operated in a lower power region is designed to have high impedance, so that it is possible to innovatively decrease a size of the Doherty amplifier and prevent additional power loss by removing the compensation line, thereby achieving higher efficiency.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A compact RF power amplifier, comprising:
a Doherty amplifier comprising a carrier amplifier comprising a first input impedance matching unit configured to match input impedance of an input first RF signal, a first amplifier configured to amplify the first RF signal matched by the first input impedance matching unit to a first RF amplified signal, and a first output impedance matching unit configured to match output impedance of the first RF amplified signal, and a peaking amplifier comprising a second input impedance matching unit configured to match input impedance of input second RF signal, a second amplifier configured to amplify the second RF signal matched by the second input impedance matching unit to a second RF amplified signal, and a second output impedance matching unit configured to match output impedance of the second RF amplified signal,
wherein when a power level of the first RF amplified signal reaches a predetermined power level, the peaking amplifier outputs the second RF amplified signal.

2. A compact RF power amplifier, comprising:
a Doherty amplifier comprising a carrier amplifier comprising a first input impedance matching unit configured to match input impedance of an input first RF signal, a first amplifier configured to amplify the first RF signal matched by the first input impedance matching unit to a first RF amplified signal, and a first output impedance matching unit configured to match output impedance of the first RF amplified signal, and a peaking amplifier comprising a second input impedance matching unit configured to match input impedance of input second RF signal, a second amplifier configured to amplify the second RF signal matched by the second input impedance matching unit to a second RF amplified signal, and a second output impedance matching unit configured to match output impedance of the second RF amplified signal;
a first quarter wave transformer connected to the first output impedance matching unit, and configured to maintain the first RF amplified signal with impedance of 50Ω; and
a second quarter wave transformer connected to the first quarter wave transformer and the second output impedance matching unit, and configured to output a third RF signal combined with at least one of the first and second RF amplified signals,
wherein when a power level of the first RF amplified signal reaches a predetermined power level, the peaking amplifier outputs the second RF amplified signal, and the third RF signal is the same as the first RF amplified signal before the predetermined power level, and is the same as a combined signal of the first and second RF amplified signals after the predetermined power level.

3. The compact RF power amplifier of claim 1 or 2, further comprising:
a distributor configured to distribute an input RF signal to the first RF signal and the second RF signal with a phase delay of 90° compared to a phase of the first RF signal.

4. The compact RF power amplifier of claim 3, wherein the distributor is a hybrid coupler or a power distributor.

5. The compact RF power amplifier of claim 1 or 2, wherein the Doherty amplifier is a microwave monolithic integrated circuit (MMIC) chip.

6. The compact RF power amplifier of claim 1 or 2, wherein when the first RF amplified signal has a power level equal to or higher than the predetermined power level, the second output impedance matching unit maintains impedance of 45Ω to 55Ω, and when the first RF amplified signal has a power level lower than the predetermined power level, the second output impedance matching unit maintains impedance higher than the impedance of 50Ω.
